(19) United States
(12) Patent Application Publication
(10) Pub. No.: US 2024/0186763 A1
(43) Pub. Date: Jun. 6, 2024

(54) METHOD OF MANUFACTURING SEMICONDUCTOR OPTICAL DEVICE

(71) Applicant: Sumitomo Electric Industries, Ltd., Osaka (JP)

(72) Inventor: Takehiko KIKUCHI, Osaka-shi (JP)

(73) Assignee: Sumitomo Electric Industries, Ltd., Osaka (JP)

(21) Appl. No.: 18/512,192

(22) Filed: Nov. 17, 2023

(30) Foreign Application Priority Data
Dec. 2, 2022 (JP) 2022-193660

(51) Int. Cl. H01S 5/02

(52) U.S. Cl. CPC H01S 5/0215; H01S 5/021; H01S 5/026

(57) ABSTRACT

A method of manufacturing a semiconductor optical device is a method of manufacturing a semiconductor optical device includes a first substrate and a semiconductor device, the first substrate including a silicon layer, and the semiconductor device having an optical gain. The semiconductor device has at least one hole extending halfway through the semiconductor device from a first surface toward a second surface opposite to the first surface. The method includes bonding the first surface of the semiconductor device to the silicon layer of the first substrate, and exposing the at least one hole of the semiconductor device by removing a portion of the semiconductor device including the second surface after the bonding.

### CROSS REFERENCE TO RELATED APPLICATIONS

This application claims priority based on Japanese Patent Application No. 2022-193660 filed on Dec. 2, 2022, and the entire contents of the Japanese patent application are incorporated herein by reference.

### TECHNICAL FIELD

The present disclosure relates to a method of manufacturing a semiconductor optical device.

### BACKGROUND

There is known a technique for bonding a semiconductor device formed of a compound semiconductor and having an optical gain to a substrate such as an SOI (Silicon On Insulator) substrate (silicon photonics) on which a waveguide is formed. In order to increase bonding strength, heat treatment is performed. In the heat treatment, the temperature is about several hundred degrees. In the heat treatment, gas is generated from a bonding interface. The gas generates bulges (voids) at the bonding interface. There has been developed a technique for providing a structure (outgas structure) for releasing gas, such as a hole or a groove, on a front surface of an SOI substrate (for example, Non-PTL 1: D. Liang, J. E. Bowers “Highly efficient vertical outgassing channels for low-temperature InP-to-silicon direct wafer bonding on the silicon-on-insulator substrate”, Journal of Vacuum Science & Technology B: Microelectronics and Nanometer Structures Processing, Measurement, and Phenomena 26, 1560 (2008)). By allowing the gas to release from the outgas structure, generation of voids can be suppressed.

### SUMMARY

A method of manufacturing a semiconductor optical device according to the present disclosure is a method of manufacturing a semiconductor optical device including a first substrate and a semiconductor device, the first substrate including a silicon layer, and the semiconductor device having an optical gain. The semiconductor device has at least one hole extending halfway through the semiconductor device from a first surface toward a second surface opposite to the first surface. The method includes: bonding the first surface of the semiconductor device to the silicon layer of the first substrate; and exposing the at least one hole of the semiconductor device by removing a portion of the semiconductor device including the second surface after the bonding.

### BRIEF DESCRIPTION OF THE DRAWINGS

FIG. 1A is a perspective view illustrating a semiconductor optical device according to a first embodiment.

FIG. 1B is a cross-sectional surface view taken along line A-A of FIG. 1A.

FIG. 2 is a cross-sectional surface view illustrating a small piece.

FIG. 3 is a plan view illustrating a substrate.

FIG. 4 is an enlarged plan view of one small piece.

FIG. 5 is an enlarged plan view of the vicinity of one waveguide.

FIG. 6A is a cross-sectional surface view illustrating a method of manufacturing a semiconductor optical device.

FIG. 6B is a cross-sectional surface view illustrating a method of manufacturing a semiconductor optical device.

FIG. 7 is a cross-sectional surface view illustrating a small piece.

FIG. 8A illustrates a method of manufacturing a semiconductor optical device.

FIG. 8B illustrates a method of manufacturing a semiconductor optical device.

FIG. 8C illustrates a method of manufacturing a semiconductor optical device.

### DETAILED DESCRIPTION

The SOI substrate is provided with a structure of an element such as a waveguide. It has been difficult to provide both the outgas structure and the element structure on the SOI substrate. It is therefore an object of the present disclosure to provide a method of manufacturing a semiconductor optical device capable of suppressing the generation of voids and forming the element structure.

### Description of Embodiments of Present Disclosure

First, the contents of embodiments of the present disclosure will be listed and explained.

(1) An embodiment according to the present disclosure is a method of manufacturing a semiconductor optical device including a first substrate and a semiconductor device, the first substrate including a silicon layer, and the semiconductor device having an optical gain. The semiconductor device has at least one hole extending halfway through the semiconductor device from a first surface toward a second surface opposite to the first surface. The method includes bonding the first surface of the semiconductor device to the silicon layer of the first substrate; and exposing the at least one hole of the semiconductor device by removing a portion of the semiconductor device including the second surface after the bonding. In the bonding, gas is generated at the bonding interface between the semiconductor device and the first substrate. The gas enters the hole. By exposing the hole, the gas is released out of the hole. Therefore, generation of voids at the bonding interface is suppressed. An element structure can be formed by processing the semiconductor device after bonding.

(2) In the above (1), the bonding may include bringing the first surface of the semiconductor device into contact with the silicon layer and heating the first surface of the semiconductor device and the silicon layer. The heating increases the bonding strength. On the other hand, gas is generated from the bonding interface by heating. Since the gas enters the hole, the generation of voids at the bonding interface is suppressed.

(3) In the above (1) or (2), the silicon layer may include a waveguide. The semiconductor device may have a first region and a second region. The second region may have a plurality of the holes. The plurality of holes may include the at least one hole. In the bonding, the first region may be bonded to a position at which the first region overlaps the waveguide. Since the second region includes a plurality of holes, the generation of voids is suppressed. The element structure can be formed from the first region.

(4) In the above (3), a distance between the first region and at least one hole adjacent to the first region in the plurality of holes may be 50 μm or less. Since the gas generated in the first region is accumulated in the holes, the generation of voids is suppressed.

(5) In any one of above (1) to (4), the semiconductor device may include a second substrate and a semiconductor layer. A surface of the semiconductor layer opposite to the second substrate may be the first surface. A surface of the second substrate opposite to the semiconductor layer may be the second surface. The hole may extend through the semiconductor layer and extend halfway through the second substrate. The exposing the hole may include removing the second substrate. By removing the second substrate, the hole is exposed. The gas is released out of the hole. Generation of voids is suppressed.

(6) In any one of above (1) to (4), the semiconductor device may include a second substrate, a first semiconductor layer, and a second semiconductor layer. The second semiconductor layer may be disposed between the second substrate and the first semiconductor layer. A surface of the first semiconductor layer opposite to the second substrate may be the first surface. A surface of the second substrate opposite to the first semiconductor layer may be the second surface. The hole extends through the first semiconductor layer and extends to a front surface of the second semiconductor layer. The manufacturing method may include removing the second substrate by etching after the bonding and before the exposing. The exposing the hole may include removing the second semiconductor layer. In the etching of the second substrate, the first semiconductor layer is protected by the second semiconductor layer, so that it is hard to be etched. The hole is exposed by removing the second semiconductor layer. The gas is released out of the hole. The generation of voids is suppressed.

(7) In any one of above (1) to (6), the semiconductor device may have a plurality of holes. The plurality of holes may include the at least one hole. A distance between two of the plurality of holes may be 200 μm or less. Since the gas generated from between the holes accumulates in the hole, the generation of voids is suppressed.

(8) In any one of above (1) to (7), a size of the hole when viewed in plan view may be m or more. The volume of the hole increases. Since the gas is accumulated in the hole, the generation of voids is suppressed.

(9) In any one of above (1) to (8), a depth of the hole may be 2 μm or more. The volume of the hole increases. Since the gas is accumulated in the hole, the generation of voids is suppressed.

### Details of Embodiments of Present Disclosure

A specific example of a method of manufacturing a semiconductor optical device according to an embodiment of the present disclosure will be described below with reference to figures (FIGs). The present disclosure is not limited to these examples, and is defined by the scope of the claims, and is intended to include all modifications within the meaning and scope equivalent to the scope of the claims.

### First Embodiment

### (Semiconductor Optical Device)

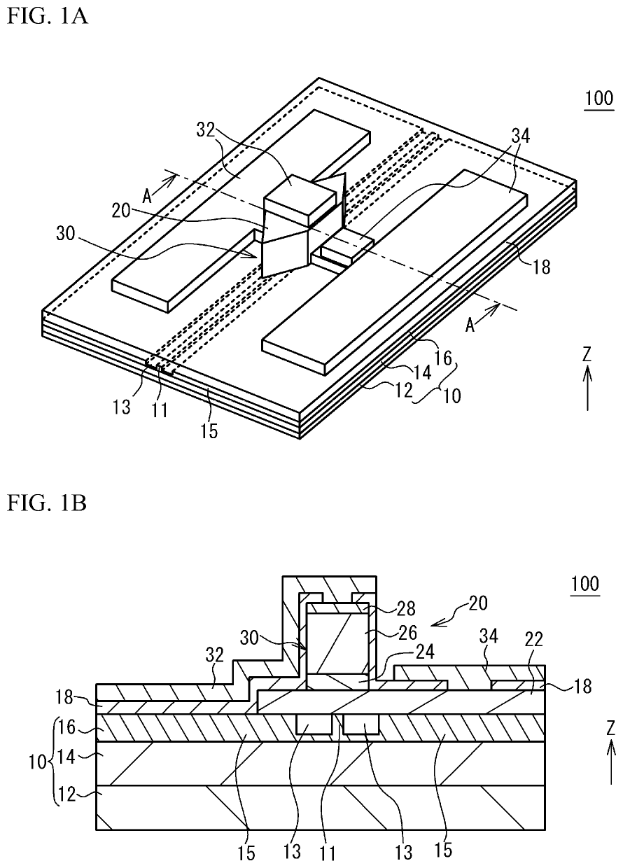

FIG. 1A is a perspective view illustrating a semiconductor optical device 100 according to a first embodiment. FIG. 1B is a cross-sectional surface view taken along line A-A of FIG. 1A. As illustrated in FIGS. 1A and 1, semiconductor optical device 100 is a hybrid laser device having a substrate 10 (first substrate) and a semiconductor device 20. Semiconductor device 20 has an optical gain and generates light. Substrate 10 propagates light. The Z-axis direction is a normal direction of the upper surface of substrate 10.

As illustrated in FIG. 1B, substrate 10 is an SOI substrate including a substrate 12, a box layer 14, and a silicon (Si) layer 16 sequentially stacked in the Z-axis direction. Substrate 12 is formed of, for example, Si. Box layer 14 is formed of, for example, silicon oxide (SiO₂). Box layer 14 has a thickness of 3 μm, for example. Si layer 16 has a thickness of 220 nm, for example. The upper surface of substrate 10 is covered with an electrically insulating film 18. Electrically insulating film 18 is formed of SiO₂ having a thickness of 1 μm, for example. The refractive index of Si layer 16 is 3.45. The refractive index of box layer 14 and electrically insulating film 18 is 1.45, which is lower than that of Si layer 16.

Si layer 16 of substrate 10 has a waveguide 11, two recesses 13, and two terraces 15. Waveguide 11 and recesses 13 extend in the same direction. Two recesses 13 are positioned on both sides of waveguide 11 and extend in the same direction as waveguide 11. Terrace 15 is a flat surface of Si layer 16 and is positioned opposite to waveguide 11 with respect to recess 13. Although the bottom surface of recesses 13 is Si layer 16 in FIG. 1B, the bottom surface may be box layer 14. Si layer 16 may be disposed with optical components such as a ring resonator and a loop mirror. For example, the ring resonator is formed by bending waveguide 11 in a ring shape.

As illustrated in FIG. 1B, semiconductor device 20 is bonded to an upper surface of Si layer 16, on waveguide 11 and recess 13. Semiconductor device 20 includes a cladding layer 22, an active layer 24, a cladding layer 26, and a contact layer 28. Cladding layer 22 to contact layer 28 are sequentially stacked on top of one another from the upper surface of substrate 10.

Cladding layer 22 is formed of n-type indium phosphide (n-InP) having a thickness of 400 nm, for example. Cladding layer 26 is formed of p-InP having a thickness of 2 μm, for example. Contact layer 28 is formed of (p+)-gallium indium arsenide (GaInAs), for example. Active layer 24 includes a plurality of well layers and barrier layers alternately stacked, and has an MQW (Multi Quantum Well) structure. The well layers and the barrier layers are formed of, for example, non-doped gallium indium arsenide phosphide (i-GaInAsP). Active layer 24 has a thickness of 300 nm, for example. Active layer 24 has an optical gain and emits light having a wavelength of 1.55 μm, for example. Each layer of semiconductor device 20 may be formed of a III-V compound semiconductor other than those described above.

As illustrated in FIG. 1A, semiconductor device 20 includes a mesa 30 and electrodes 32 and 34. Mesa 30 in semiconductor device 20 is positioned over waveguide 11. Mesa 30 has a tapered tip, which tapers along waveguide 11. Mesa 30 in semiconductor device 20 and the tapered tip are the element structure.

As illustrated in FIG. 1B, mesa 30 is formed of active layer 24, cladding layer 26 and contact layer 28 and is positioned over waveguide 11. Cladding layer 22 is positioned between mesa 30 and substrate 10 and extends outside mesa 30. Cladding layer 22 is in contact with an upper surface of waveguide 11 and an upper surface of terrace 15 in substrate 10. A front surface of mesa 30 and cladding layer 22 is covered by electrically insulating film 18. Electrically insulating film 18 has openings on mesa 30 and on cladding layer 22.

As illustrated in FIG. 1B, electrode 32 extends from the top of mesa 30 to an upper surface of electrically insulating film 18 outside mesa 30. Electrode 32 is electrically connected to contact layer 28 through the opening in electrically insulating film 18. Electrode 32 is formed of, for example, a laminate of titanium, platinum, and gold (Ti/Pt/Au). Electrode 34 is spaced apart from electrode 32 and is disposed on the upper surface of electrically insulating film 18 and is electrically connected to cladding layer 22 through the opening in electrically insulating film 18. Electrode 34 is formed of a metal such as an alloy of gold, germanium, and nickel (AuGeNi). A plating layer of Au or the like may be disposed on electrode 32 and electrode 34.

A voltage is applied to electrodes 32 and 34 to inject carriers into active layer 24 of semiconductor device 20. By injecting carriers, active layer 24 generates light. Semiconductor device 20 and substrate 10 are evanescently optically coupled to each other, and the light transits to waveguide 11 in substrate 10. The light propagates through waveguide 11 and is emitted from the end of substrate 10 to the outside of semiconductor optical device 100.

Semiconductor optical device 100 includes substrate 10 and semiconductor device 20. In the manufacturing process, semiconductor device 20 is bonded to substrate 10. Gas is generated from an interface between substrate 10 and semiconductor device 20. When the gas forms voids, the bonding strength between substrate 10 and semiconductor device 20 is reduced, and semiconductor device 20 is easily peeled off. In the present disclosure, the generation of voids is suppressed by allowing gas to release.

### (Method of Manufacturing)

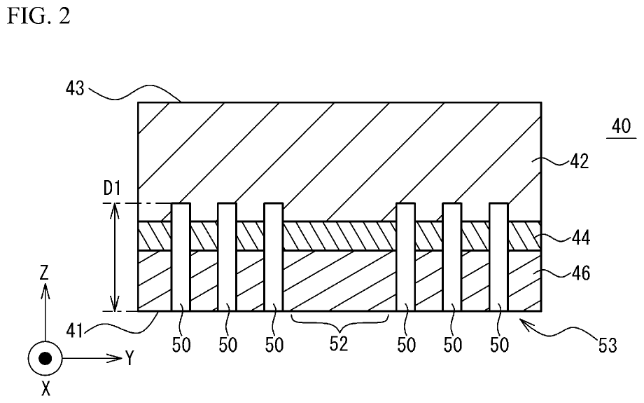

FIGS. 2 to 6B illustrate a method of manufacturing semiconductor optical device 100. FIG. 2 is a cross-sectional surface view illustrating a small piece 40. Small piece 40 is formed by dicing a group III-V compound semiconductor wafer. Semiconductor device 20 illustrated in FIGS. 1A and 1B is formed from small piece 40. Small piece 40 includes a substrate 42 (second substrate), an etching-stop layer 44 and a semiconductor layer 46. Semiconductor layer 46 includes cladding layer 22, active layer 24, cladding layer 26 and contact layer 28 illustrated in FIG. 1B. A surface 41 (first surface) of small piece 40 is a front surface of cladding layer 22.

Etching-stop layer 44 is disposed on contact layer 28 in semiconductor layer 46. Substrate 42 is disposed on etching-stop layer 44. A surface 43 (second surface) opposite to surface 41 of small piece 40 is a front surface of substrate 42. Substrate 42 is formed of, for example, indium phosphide (InP) having a thickness of 350 μm. Etching-stop layer 44 is formed of indium gallium arsenide (InGaAs) having a thickness of 0.3 μm, for example.

As illustrated in FIG. 2, small piece 40 has a region 52 (first region) and a region 53 (second region). A plurality of holes 50 are provided in region 53. After the epitaxial growth of semiconductor layer 46, a mask and a resist pattern (both not illustrated) are formed on a front surface of semiconductor layer 46. The resist pattern is transferred to the mask. Hole 50 is formed by etching or the like using the mask. Hole 50 extends from surface 41 to surface 43. Hole 50 extends through semiconductor layer 46 and etching-stop layer 44 and extends halfway through substrate 42. A depth D1 of hole 50 (i.e., a distance from surface 41 to a bottom surface of hole 50) is, for example, 2 μm or more. Hole 50 functions as an outgas structure that allows gas to release.

Hole 50 is not provided in region 52. By processing region 52, semiconductor device 20 illustrated in FIGS. 1A and 1B is formed.

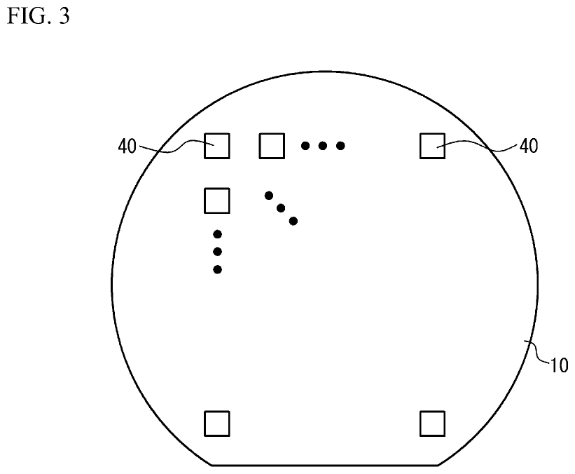

FIG. 3 is a plan view illustrating substrate 10. Substrate 10 is, for example, a 2-inch wafer. Before bonding small piece 40, Si layer 16 of substrate 10 is etched to form waveguide 11. As illustrated in FIG. 3, a plurality of small pieces 40 are bonded to the upper surface of substrate 10. In the example of FIG. 3, 64 small pieces 40 are bonded to one wafer.

Examples of the bonding method include hydrophilic bonding or plasma-activated bonding. In the hydrophilic bonding, for example, the upper surface of substrate 10 and a front surface of small piece 40 are irradiated with oxygen plasma and exposed to the atmosphere. Hydroxyl groups (—OH) are generated on the upper surface of substrate 10 and the front surface of small piece 40. The upper surface of substrate 10 is brought into contact with the front surface of small piece 40 for temporary bonding. After the contact, heat treatment is performed at a temperature of, for example, 300° C. to increase the bonding strength. In the plasma activated bonding, the upper surface of substrate 10 and the front surface of small piece 40 are irradiated with plasma to activate these surfaces. The activated upper surface of substrate 10 is brought into contact with the activated front surface of small piece 40 for temporary bonding. After the contact, heat treatment is performed at a temperature of, for example, 300° C. to increase the bonding strength.

In both the hydrophilic bonding and the plasma-activated bonding, outgas is generated from moisture, impurities, and the like on the front surface in the heat treatment. In particular, gas is easily generated in the hydrophilic bonding.

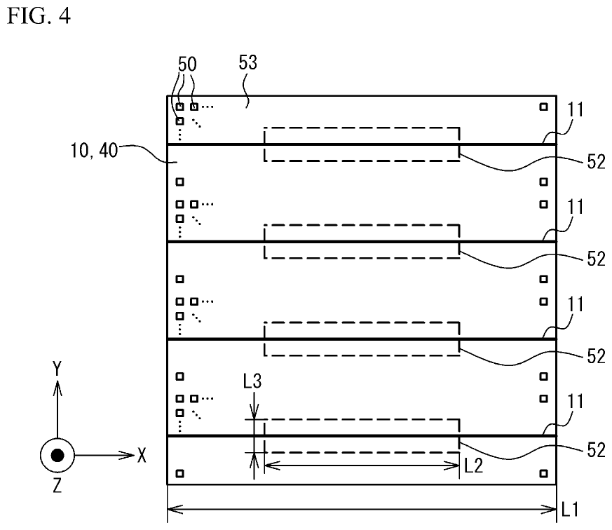

FIG. 4 is an enlarged plan view of one small piece 40. Two sides of small piece 40 are parallel to the X-axis direction, and the other two sides are parallel to the Y-axis direction. A side length L1 of small piece 40 is, for example, 2000 μm. As illustrated in FIG. 4, small piece 40 has region 52 (the first region) and region 53 (the second region). Region 52 is positioned over waveguide 11. One small piece 40 has four regions 52. A length L2 of region 52 in the X-axis direction is, for example, 1000 μm. A length L3 in the Y-axis direction is, for example, 100 μm. Region 52 does not have hole 50. Region 53 is positioned outside region 52 and has a plurality of holes 50. The plurality of holes 50 are periodically arranged in the X-axis direction and the Y-axis direction.

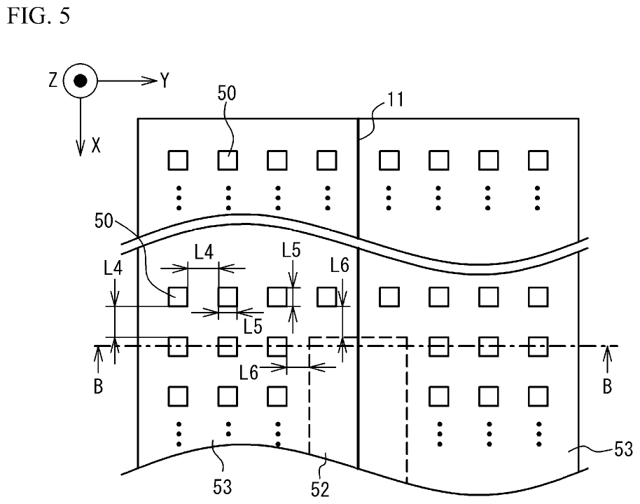

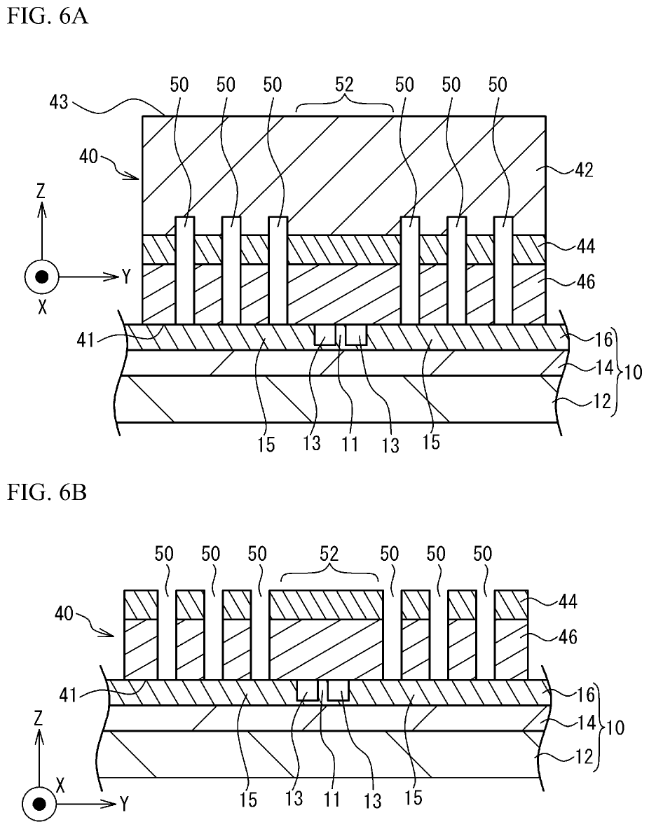

FIG. 5 is an enlarged plan view of the vicinity of one waveguide 11. FIGS. 6A and 6B are cross-sectional surface views illustrating a method of manufacturing semiconductor optical device 100, illustrating the cross-sectional surface along line B-B of FIG. 5. As illustrated in FIG. 5, a distance L4 between two adjacent holes 50 is, for example, 50 μm. The planar surface shape of hole 50 is, for example, a square. A side length L5 of hole 50 is, for example, 20 μm when viewed in plan view. A distance L6 between region 52 and hole 50 adjacent to region 52 is, for example, 30 μm.

As illustrated in FIG. 6A, surface 41 of small piece 40 is in contact with the upper surface of substrate 10. Hole 50 extends upward from the bonding interface between small piece 40 and substrate 10. Hole 50 is sealed by substrate 10 and substrate 42 in small piece 40.

After small piece 40 is temporarily bonded to substrate 10, the bonding strength is increased by heat treatment. When the temperature is raised to about 300° C., gas is generated from the bonding interface between small piece 40 and substrate 10. The gas diffuses from the bonding interface and accumulates in hole 50. Therefore, the generation of voids is suppressed.

As illustrated in FIG. 6B, substrate 42 of small piece 40 is removed by wet etching. The wet etching stops at etching-stop layer 44 and does not proceed to semiconductor layer 46. By removing substrate 42, hole 50 is exposed. Hole 50 reaches the outside of small piece 40 and is open to the outside air. The gas accumulated in hole 50 is released to the outside of hole 50.

Mesa 30 illustrated in FIG. 1A and FIG. 1B is formed by processing such as etching region 52. Electrodes 32 and 34 are formed by vacuum deposition or the like. Dicing is performed on substrate 10, and a portion of substrate 10 to which region 52 is bonded is cut out as a chip. Through the above steps, semiconductor optical device 100 is formed. A portion of small piece 40 other than region 52 does not constitute semiconductor optical device 100.

According to the first embodiment, small piece 40 (semiconductor device) has holes 50. Hole 50 extends halfway through small piece 40 from surface 41 to surface 43. As illustrated in FIG. 6B, surface 41 of small piece 40 is bonded to the upper surface of substrate 10. In the bonding process, gas is generated from the bonding interface. The gas diffuses from the bonding interface and accumulates in hole 50. Since the gas enters hole 50 and is unlikely to remain at the bonding interface, the formation of voids is suppressed. A decrease in bonding strength is suppressed, and small piece 40 is less likely to be peeled off from substrate 10.

Substrate 10 has waveguide 11 and the like, but does not have hole 50. The influence of the outgas structure on the element structure of substrate 10 is suppressed. By processing region 52 in small piece 40, semiconductor device 20 illustrated in FIGS. 1A and 1B is formed. Semiconductor device 20 has the element structure such as mesa 30. Voids are less likely to generate at the bonding interface between semiconductor device 20 and substrate 10. Voids can be suppressed and the element structure can be formed.

The bonding method is, for example, hydrophilic bonding or plasma-activated bonding. In the bonding, surface 41 of small piece 40 is brought into contact with the upper surface of substrate 10 for temporary bonding. After the temporary bonding, heat treatment is performed at a temperature of, for example, 300° C. to increase the bonding strength. By heating, moisture is evaporated and gas is generated. Gases are also released from organic components. The generation of voids is suppressed by the accumulation of such outgas in hole 50.

Si layer 16 of substrate 10 has waveguide 11. As illustrated in FIGS. 6A and 6B, region 52 in small piece 40 is bonded to a position at which region 52 overlaps waveguide 11. By processing region 52, mesa 30 of semiconductor device 20 is formed on waveguide 11 as illustrated in FIG. 1A. As illustrated in FIG. 6A, region 53 in small piece 40 is provided with a plurality of holes 50. Since the gas is accumulated in hole 50, the generation of voids is suppressed. In the process of forming semiconductor device 20, region 53 is removed. Region 52 does not have hole 50. The influence of hole 50 on semiconductor device 20 is unlikely to generate.

When the distance L6 between region 52 and hole 50 adjacent to region 52 is large, the gas generated at the interface surface between region 52 and substrate 10 is less likely to diffuse to hole 50. When the gas remains at the interface, voids may be generated in region 52. By setting the distance L6 to, for example, 50 μm or less, the gas generated at the interface between region 52 and substrate 10 diffuses to hole 50. The generation of voids in region 52 is suppressed.

As illustrated in FIG. 6A, small piece 40 immediately after bonding has substrate 42. Hole 50 extends halfway through substrate 42 from surface 41. As illustrated in FIG. 6B, substrate 42 is removed by wet etching to expose hole 50. The gas accumulated in hole 50 is released to the outside.

The size and the number of holes 50 are determined in consideration of the total volume of the outgas generated at the bonding interface. Increasing the total volume of the plurality of holes 50 allows the outgas to be stored in holes 50.

The length L5 and the depth D1 of hole 50 determine the volume of hole 50. When the volume of hole 50 is small, the gas cannot enter hole 50 completely. Voids are generated by the gas. When the volume of hole 50 is large, gas is less likely to enter hole 50 and remain at the interface. Generation of voids is suppressed. The length L5 of hole 50 is, for example, 20 μm, and may be 5 μm or more, 10 μm or more, or the like. The depth D1 is, for example, 2 μm or more, and may be 3 μm or more, 5 μm or more, or 10 μm or more. Hole 50 may extend through semiconductor layer 46 and etching-stop layer 44 and extend halfway through substrate 42.

When the plurality of holes 50 are separated from each other, the gas generated in the portion between holes 50 is less likely to diffuse to holes 50. When holes 50 approach each other, the gas is diffused to holes 50. The distance L4 between two adjacent holes 50 is, for example, 50 m, and may be 200 μm or less.

When the distance L4 between holes 50 is reduced, the density of holes 50 in surface 41 can be increased and the number of holes 50 can be increased. As the number of holes 50 increases, the total volume increases. The volume per hole 50 may be small. On the other hand, when the number of holes 50 is reduced, the volume of each holes 50 may be increased. The distance L4 between holes 50, the length L5 of hole 50, and the depth D1 of hole 50 may satisfy the following formula.

L4²/(D1×L5²)<800 μm⁻¹

The planar surface shape of hole 50 may be a rectangle, a polygon, or a shape including a curved line (such as an ellipse). The number of regions 52 in one small piece 40 may be four or less or may be four or more. Substrate 10 may be disposed with an optical element other than waveguide 11, such as a ring resonator. Semiconductor device 20 may be formed of the above-described compound semiconductor or may be formed of another compound semiconductor. Substrate 10 may be an SOI substrate or another substrate.

### Second Embodiment

Description of the same configuration as that of the first embodiment will be omitted. Also in the second embodiment, semiconductor optical device 100 illustrated in FIGS. 1A and 1B is manufactured.

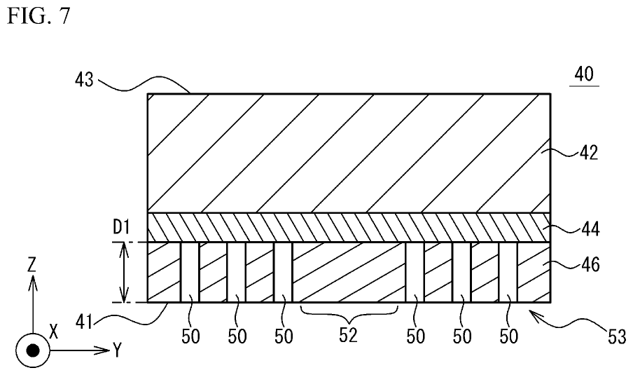

FIG. 7 is a cross-sectional surface view illustrating small piece 40. As illustrated in FIG. 7, hole 50 extends from surface 41 of small piece 40 to the interface between semiconductor layer 46 and etching-stop layer 44. Hole 50 extends through semiconductor layer 46, but does not extend through etching-stop layer 44 and substrate 42. Small piece 40 is bonded to substrate 10.

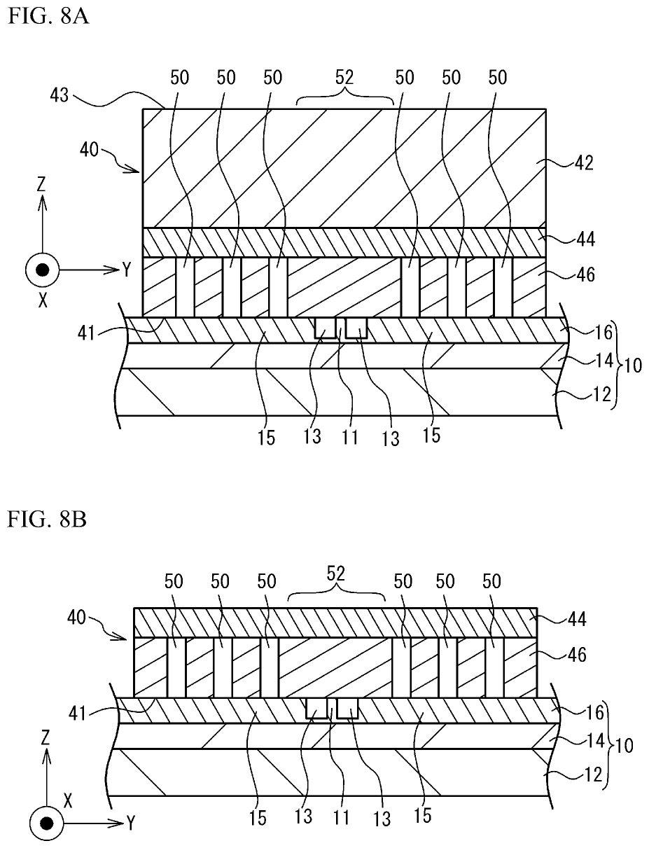

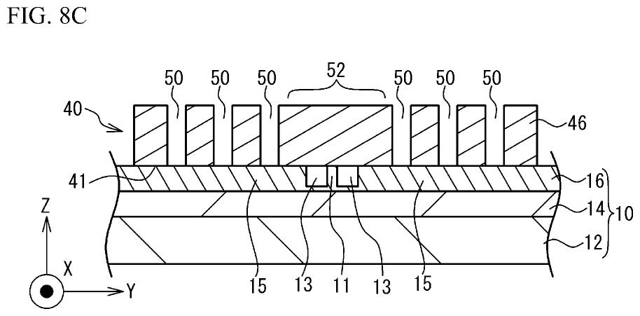

FIGS. 8A to 8C illustrate a method of manufacturing semiconductor optical device 100. As illustrated in FIG. 8A, small piece 40 is bonded to the upper surface of substrate 10. Examples of the bonding method include a hydrophilic bonding and a plasma-activated bonding. Surface 41 of small piece 40 is in contact with the upper surface of substrate 10. Hole 50 is sealed by substrate 10 and etching-stop layer 44 of small piece 40.

After small piece 40 is temporarily bonded to substrate 10, the bonding strength is increased by heat treatment. When the temperature is raised to about 300° C., gas is generated from the interface between small piece 40 and substrate 10. The gas exits from the interface and accumulates in hole 50. Therefore, the generation of voids is suppressed.

As illustrated in FIG. 8B, substrate 42 of small piece 40 is removed by wet etching using, for example, hydrochloric acid as an etchant. The wet etching stops at etching-stop layer 44 and does not proceed to semiconductor layer 46. Hole 50 is closed by etching-stop layer 44. Therefore, the etchant is unlikely to enter the inside of hole 50. Etching of semiconductor layer 46 is suppressed.

As illustrated in FIG. 8C, etching-stop layer 44 is removed to expose holes 50. The gas in hole 50 is released to the atmosphere. By processing such as etching region 52, semiconductor optical device 100 illustrated in FIGS. 1A and 1B is formed. A portion of small piece 40 other than region 52 does not constitute semiconductor optical device 100.

According to the second embodiment, small piece 40 has hole 50. In the bonding process, gas is generated from the bonding interface and accumulated in hole 50. Since the gas enters hole 50, the formation of voids is suppressed. A decrease in bonding strength is suppressed, and small piece 40 is less likely to be peeled off from substrate 10.

As illustrated in FIG. 8B, substrate 42 is removed by wet etching after the bonding. The etching stops at etching-stop layer 44. Hole 50 extends from surface 41 to the front surface of etching-stop layer 44 and is closed by etching-stop layer 44. Therefore, the etchant is less likely to go into hole 50. Etching of semiconductor layer 46 by the etchant is suppressed. Since semiconductor layer 46 in region 52 is not etched, the influence of etching on semiconductor device 20 is suppressed.

Hole 50 is necessary not to extend through etching-stop layer 44, and may extend halfway through etching-stop layer 44, for example.

Although the embodiments of the present disclosure have been described in detail above, the present disclosure is not limited to the specific embodiments, and various modifications and changes can be made within the scope of the gist of the present disclosure described in the claims.

What is claimed is:

1. A method of manufacturing a semiconductor optical device including a first substrate and a semiconductor device, the first substrate including a silicon layer, and the semiconductor device having an optical gain,
wherein the semiconductor device has at least one hole extending halfway through the semiconductor device from a first surface toward a second surface opposite to the first surface,
the method comprising:
bonding the first surface of the semiconductor device to the silicon layer of the first substrate; and
exposing the at least one hole of the semiconductor device by removing a portion of the semiconductor device including the second surface after the bonding.

2. The method of manufacturing the semiconductor optical device according to claim 1,
wherein the bonding includes bringing the first surface of the semiconductor device into contact with the silicon layer and heating the first surface of the semiconductor device and the silicon layer.

3. The method of manufacturing the semiconductor optical device according to claim 1,
wherein the silicon layer includes a waveguide,
the semiconductor device has a first region and a second region,
the second region has a plurality of holes,
the plurality of holes include the at least one hole and in the bonding, the first region is bonded to a position of the first substrate at which the first region overlaps the waveguide.

4. The method of manufacturing the semiconductor optical device according to claim 3,
wherein a distance between the first region and at least one hole adjacent to the first region in the plurality of holes is 50 μm or less.

5. The method of manufacturing the semiconductor optical device according to claim 1,
wherein the semiconductor device includes a second substrate and a semiconductor layer,
a surface of the semiconductor layer opposite to the second substrate is the first surface,
a surface of the second substrate opposite to the semiconductor layer is the second surface,
the hole extends through the semiconductor layer and extends halfway through the second substrate, and
the exposing the hole includes removing the second substrate.

6. The method of manufacturing the semiconductor optical device according to claim 1,
wherein the semiconductor device includes a second substrate, a first semiconductor layer, and a second semiconductor layer,
the second semiconductor layer is disposed between the second substrate and the first semiconductor layer,
a surface of the first semiconductor layer opposite to the second substrate is the first surface,
a surface of the second substrate opposite to the first semiconductor layer is the second surface,
the hole extends through the first semiconductor layer and extends to a front surface of the second semiconductor layer,
the manufacturing method includes removing the second substrate by etching after the bonding and before the exposing, and
the exposing the hole includes removing the second semiconductor layer.

7. The method of manufacturing the semiconductor optical device according to claim 1,
wherein the semiconductor device has a plurality of holes,
the plurality of holes include the at least one hole and
wherein a distance between two of the plurality of holes is 200 μm or less.

8. The method of manufacturing the semiconductor optical device according to claim 1,
wherein a size of the hole when viewed in plan view is 5 μm or more.

9. The method of manufacturing the semiconductor optical device according to claim 1,
wherein a depth of the hole is 2 μm or more.
